(19) United States
(12) Patent Application Publication
(10) Pub. No.: US 2008/0105902 A1
(43) Pub. Date: May 8, 2008

(54) Rectifier

(75) Inventor: John Twynam, Yamatokooriyama-shi (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA

(21) Appl. No.: 11/976,421

(22) Filed: Oct. 24, 2007

(30) Foreign Application Priority Data
Oct. 25, 2006 (JP) 2006-289626

(51) Int. Cl. H01L 29/872

(52) U.S. Cl. 257/200; 257/E29.338

(57) ABSTRACT

In the rectifier, a barrier layer and a channel layer constitute a heterojunction portion, and a two-dimensional electron gas channel is generated in the vicinity of a boundary between the channel layer and the barrier layer. A Schottky gate electrode is connected to an anode ohmic electrode and extends from above the anode ohmic electrode over to the barrier layer and a recess formed in the barrier layer is covered with the Schottky gate electrode. The two-dimensional electron gas channel located just below the recess is depleted by the influence of the Schottky gate electrode in a state in which there is no application voltage. By virtue of the formation of the recess in the barrier layer, the threshold voltage at which electrons are generated in the two-dimensional electron gas channel located just below the gate electrode is lowered, and the rise voltage can be made lower than that of the conventional Schottky diode.

### CROSS-REFERENCE TO RELATED APPLICATION

This nonprovisional application claims priority under 35 U.S.C. §119(a) on Patent Application No(s). 2006-289626 filed in Japan on Oct. 25, 2006, the entire contents of which are hereby incorporated by reference.

### BACKGROUND OF THE INVENTION

The present invention relates to a rectifier and for example, to a rectifier that has a heterojunction portion including a III-V group compound semiconductor of GaN or the like.

Conventionally, for example, a GaN Schottky diode whose cross section is shown in FIG. 10 has been known as a rectifier (“Development of a GaN on Si electronic device for power supply” (Hirokazu Goto, Koji Ohtsuka), refer to The Institute of Electronics, Information and Communication Engineers, S45-S46, 2006). In the GaN Schottky diode, an AlN/GaN buffer layer 2002, a channel layer 2003 made of undoped GaN, and a layer 2005 made of Al_{0.25}Ga_{0.75}N are successively formed on an Si substrate 2001. A cathode ohmic electrode 2006 and an anode Schottky electrode 2009 are formed on the Al_{0.25}Ga_{0.75}N layer 2005. An Si₃N₄ insulator 2013 is formed on the layer 2005 made of AlGaN. It is noted that the reference numeral 2004 denotes a 2DEG (two-dimensional electron gas) channel.

The conventional GaN Schottky diode as the rectifier shown in FIG. 10 needs to have a Schottky barrier height of not lower than 1.5 V in order to reduce a leakage current. Therefore, in the conventional Schottky diode, its rise voltage becomes approximately equal to the Schottky barrier height.

However, the fact that the rise voltage of the diode is not lower than 1.5 V causes an increase in the device loss in many applications and is therefore undesirable.

### SUMMARY OF THE INVENTION

An object of the present invention is to provide a rectifier of a low rise voltage.

In order to achieve the above object, there is provided a rectifier comprising:

a semiconductor channel layer formed on a substrate;

a barrier layer that is formed on the semiconductor channel layer and constitutes a heterojunction portion with the semiconductor channel layer;

an anode ohmic electrode connected to the semiconductor channel layer;

a cathode ohmic electrode connected to the semiconductor channel layer;

a gate electrode that is connected to the anode ohmic electrode and formed on the heterojunction portion; and

a recess that is formed in the barrier layer and wholly covered with the gate electrode.

In the rectifier of the present invention, the anode ohmic electrode and the cathode ohmic electrode are formed on the heterojunction portion constituted of the semiconductor channel layer and the barrier layer. The anode ohmic electrode and the cathode ohmic electrode are ohmically connected to the two-dimensional electron gas (2DEG) channel formed at the boundary of the junction of the heterojunction portion. Then, the recess is formed in the barrier layer, and the recess is wholly covered with the gate electrode connected to the anode ohmic electrode.

With the above arrangements when a voltage applied across the anode ohmic electrode and the cathode ohmic electrode is not higher than 0 V, the two-dimensional electron gas in the channel layer located just below the gate electrode with which the recess is covered is depleted, and no current flows between the anode ohmic electrode and the cathode ohmic electrode. Conversely, when the voltage applied across the anode ohmic electrode and the cathode ohmic electrode is a positive voltage (forward bias), electrons are generated in the channel layer located just below the gate electrode with which the recess is covered, and a current flows between the anode ohmic electrode and the cathode ohmic electrode. That is, normally-off operation is obtained.

Then, according to the rectifier of the present invention, the rise voltage of the forward bias depends on the threshold voltage at which electrons are generated in the channel layer located just below the gate electrode, and the threshold voltage is lower than that of the conventional Schottky diode due to the formation of the recess in the barrier layer. Therefore, according to the present invention, a rectifier of a low turn-on voltage can be provided.

Moreover, in the rectifier of one embodiment, the semiconductor channel layer is made of the III-V group compound semiconductor, and therefore, the electron mobility can be improved.

Moreover, in the rectifier of one embodiment, the semiconductor channel layer is made of the GaN semiconductor, and therefore, the rectifier is suitable for high-frequency high-output applications.

Moreover, in the rectifier of one embodiment, the gate electrode is the Schottky electrode, and therefore, the rectifier is suitable for high-frequency applications.

In the rectifier of one embodiment, the rectifier further comprising: a dielectric that is formed in between the gate electrode and the barrier layer and constitutes a MIS (Metal-Insulator-Semiconductor) structure portion with the gate electrode and the barrier layer.

The present embodiment has a passivation effect on the semiconductor surface by virtue of the dielectric that constitutes the MIS structure portion.

In the rectifier of one embodiment, the rectifier further comprising: a semiconductor layer that is formed in between the substrate and the semiconductor channel layer and constitutes a double heterojunction structure portion with the barrier layer and the semiconductor channel layer.

In the present embodiment, it is difficult for the electrons in the two-dimensional electron channel to go out of the semiconductor channel layer due to the existence of the semiconductor layer that constitutes the double heterojunction structure portion, and therefore, a leakage current between the anode and the cathode can be reduced.

Also, there is provided a rectifier comprising:

a semiconductor channel layer formed on a substrate;

a barrier layer that is formed on the semiconductor channel layer and constitutes a heterojunction portion with the semiconductor channel layer;

an anode ohmic electrode connected to the semiconductor channel layer;

a cathode ohmic electrode connected to the semiconductor channel layer; and

a gate electrode that is connected to the anode ohmic electrode and formed on the heterojunction portion,

the barrier layer having a layer thickness of not greater than 100 Å.

According to the present embodiment, by making the barrier layer have a layer thickness of not greater than 100 Å, at least part of the semiconducting channel is depleted in a thermal equilibrium state by bringing the gate electrode close to the semiconducting channel. With this arrangement, rectification operation such that a current flows between the anode and the cathode at the time of the forward bias and no current flows between the anode and the cathode at the time of the reverse bias is obtained. Moreover, a threshold voltage at which electrons are generated in the two-dimensional electron gas channel located just below the gate electrode can be reduced, and the rise voltage can be lowered.

According to the rectifier of the present invention, the rise voltage of the forward bias depends on the threshold voltage at which the electrons are generated in the channel layer located just below the gate electrode, and the threshold voltage is lower than that of the conventional Schottky diode by virtue of the formation of the recess in the barrier layer. Therefore, according to the present invention, a rectifier of a low rise voltage can be provided.

### BRIEF DESCRIPTION OF THE DRAWINGS

The present invention will become more fully understood from the detailed description given hereinbelow and the accompanying drawings which are given by way of illustration only, and thus are not intended to limit the present inventions and wherein:

FIG. 1 is a sectional view showing a first embodiment of the rectifier of the present invention;

FIG. 2 is a view showing a state in which a forward bias is applied across the anode and the cathode in the first embodiment;

FIG. 3 is a view showing a state in which no voltage is applied across the anode and the cathode in the first embodiment;

FIG. 4 is a view showing a state in which a reverse bias is applied across the anode and the cathode in the first embodiment;

FIG. 5 is a sectional view showing a second embodiment of the rectifier of the present invention;

FIG. 6 is a sectional view showing a third embodiment of the rectifier of the present invention;

FIG. 7 is a characteristic graph showing the current-to-voltage characteristic of the first embodiment;

FIG. 8 is a characteristic graph showing the current-to-voltage characteristic of the Schottky diode of a prior art example;

FIG. 9 is a sectional view showing a fourth embodiment of the rectifier of the present invention;

FIG. 10 is a sectional view showing a GaN Schottky diode of a prior art example.

### DETAILED DESCRIPTION OF THE INVENTION

The present invention will be described in detail below by the embodiments shown in the drawings.

### First Embodiment

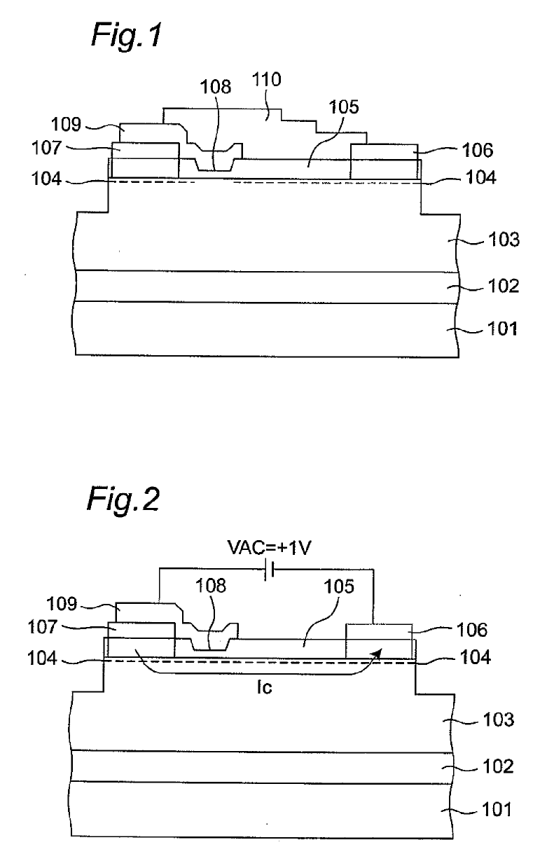

FIG. 1 shows the first embodiment of the rectifier of the present invention. In the rectifier, an AlN/GaN butter layer 102 having a layer thickness of 500 Å, a channel layer 103 made of undoped GaN having a layer thickness of 2 μm, and a barrier layer 105 made of Al_{0.3}Ga_{0.7}N having a layer thickness of 250 Å are successively formed on a silicon substrate 101.

An anode ohmic electrode 107 constructed of a laminate of Ti/Al/Au and a cathode ohmic electrode 106 constructed of a laminate of Ti/Al/Au are formed on the barrier layer 105. Then, a two-dimensional electron gas (2DEG) channel 104 is generated in the GaN channel layer 103 and in the vicinity of the boundary between the channel layer 103 and the AlGaN barrier layer 105.

The anode ohmic electrode 107 and the cathode ohmic electrode 106 are brought in ohmic contact with the two-dimensional electron gas channel 104 by heat treatment. Moreover, a recess 108 having a depth of 150 Å is formed by etching in the AlGaN barrier layer 105. Then, the recess 108 is wholly covered with a Schottky gate electrode 109 made of WN/Au. The Schottky gate electrode 109 is connected to the anode ohmic electrode 107 and extends from above the anode ohmic electrode 107 over to the barrier layer 105. The AlGaN barrier layer 105 and the GaN channel layer 103 constitute a heterojunction portion. In a state in which there is no application voltage, the two-dimensional electron gas channel 104 located just below the recess 108 is depleted by the influence of the Schottky gate electrode 109. As a result, normally-off operation is obtained.

Moreover, in the present embodiment, a Ta₂O₅ dielectric 110 is formed on the Schottky gate electrode 109, the barrier layer 105 and the cathode ohmic electrode 106. By virtue of the Ta₂O₅ dielectric 110, the withstand voltage of the device can be improved. In the present embodiment, as shown in FIG. 1 as one example, the Ta₂O₅ dielectric 110 was formed to have a stepped structure in which the thickness is reduced in steps of 8000 Å, 6000 Å and 4000 Å from the Schottky gate electrode 109 toward the cathode ohmic electrode 106. As described above, the stepped structure of the Ta₂O₅ dielectric 110 is particularly effective for the improvement of the withstand voltage. Moreover, the Ta₂O₅ dielectric 110 has the passivation effect of the semiconductor surface, and therefore, Ta₂O₅ is particularly effective as the dielectric material

Next, operation in each bias condition of the rectifier of the present embodiment is described with sequential reference to FIGS. 2 through 4.

FIG. 2 shows a state in which a forward bias is applied across the anode and the cathode in the rectifier of the present embodiment. In this state, the anode-cathode voltage V_{AC} applied across the anode and the cathode was set to +1 V. Since the rectifier has a device threshold voltage of +0.68 V, electrons are generated in the two-dimensional electron gas channel 104 located just below the recess 108 when the anode-cathode voltage V_{AC}=+1 V. As a result, the two-dimensional electron gas channel 104 comes to continuously connect (electrically conduct) the anode electrode 106 to the cathode electrode 107, and an anode current I_{C} flows.

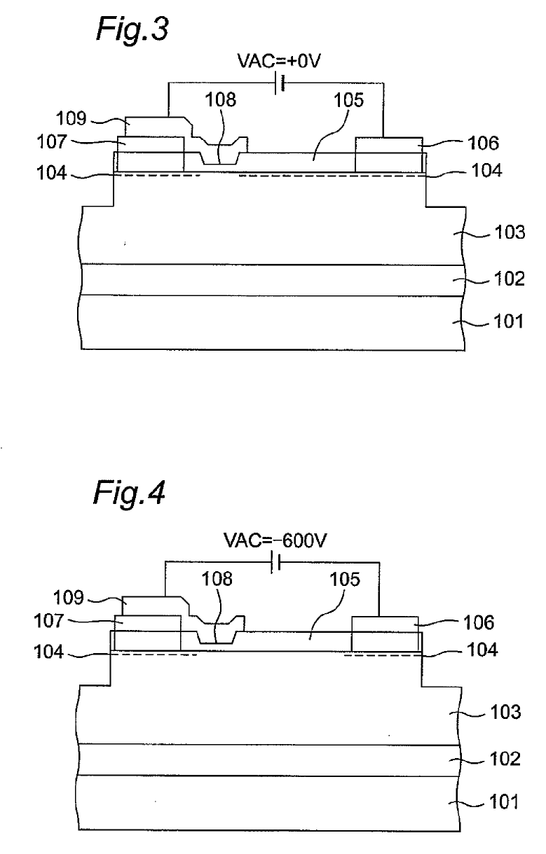

Next, FIG. 3 shows a state in which the anode-cathode voltage V_{AC} is set to 0 V in the present embodiment. Since the rectifier has the threshold voltage of +0.68 V, a region located just below the recess 108 is depleted in the two-dimensional electron gas channel 104 when V_{AC}=0 V. As a result, the two-dimensional electron gas becomes discontinuous in the two-dimensional electron gas channel 104, and the anode current I_{C} does not flow.

Next, FIG. 4 shows a state in which the anode-cathode voltage V_{AC} is set to −600 V in the present embodiment. In this state, the two-dimensional electron gas channel 104 located just below the recess 108 is depleted by the setting: V_{AC}=−600 V. As a result, the two-dimensional electron gas in the two-dimensional electron gas channel 104 becomes discontinuous, and the anode current I_{C} does not flow.

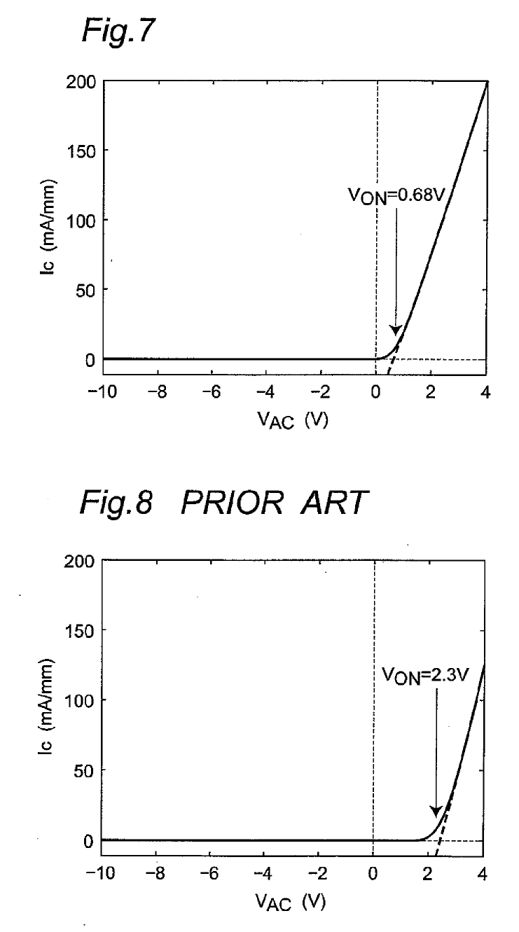

Next, FIG. 7 shows the I-V characteristic of the rectifier of the present embodiment. In the I-V characteristic of FIG. 7, the horizontal axis represents the anode-cathode voltage V_{AC} (V), and the vertical axis represents the anode current I_{C} (mA/mm). As indicated by the I-V characteristic, the rise voltage V_{ON} of the rectifier of the present embodiment is 0.68 V. In contrast to this, the rise voltage V_{ON} of the conventional Schottky diode shown in FIG. 10 is 2.3 V as indicated by the I-V characteristic of FIG. 8. That is, according to the rectifier of the present embodiment, the rise voltage was able to be largely reduced in comparison with the conventional case.

According to the rectifier of the present is embodiment, the rise voltage of the forward bias depends on the threshold voltage at which electrons are generated in the two-dimensional electron gas channel 104 located just below the gate electrode 109. The threshold voltage is lower than the rise voltage of the conventional Schottky diode, and therefore, a rectifier of which the rise voltage is lower than that of the conventional Schottky diode can be provided according to the present embodiment.

### Second Embodiment

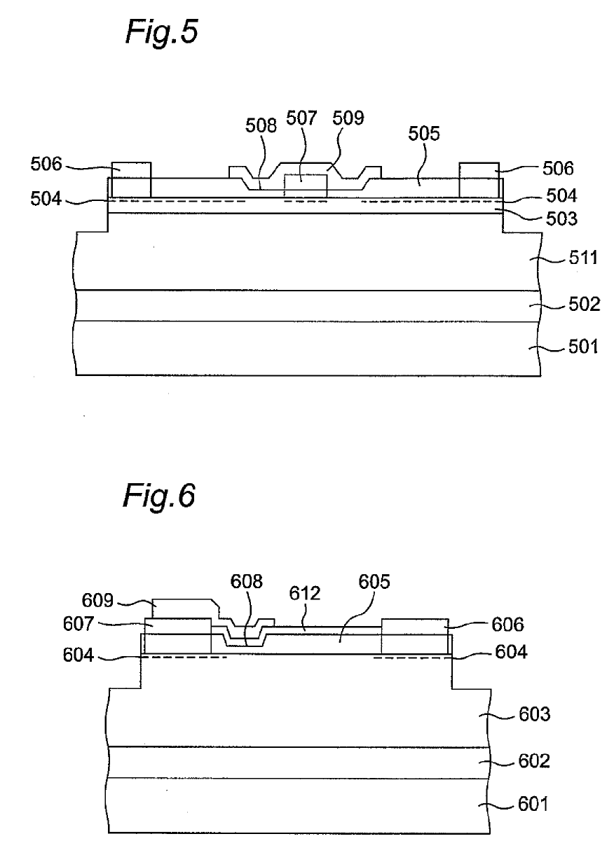

Next, FIG. 5 shows the second embodiment of the rectifier of the present invention. In the second embodiment, an AlN/GaN buffer layer 502 having a layer thickness of 500 Å, a layer 511 made of undoped Al_{0.1}Ga_{0.9}N having a layer thickness of 2 μm, a channel layer 503 made of undoped GaN having a layer thickness of 500 Å, and a barrier layer 505 made of Al_{0.3}Ga_{0.7}N having a layer thickness of 250 Å are successively formed on a silicon substrate 501. The barrier layer 505, the channel layer 503 and the AlGaN layer 511 constitute a double heterojunction structure portion.

Moreover, a recess 508 having a depth of 150 Å is formed by etching in an AlGaN barrier layer 505. An anode ohmic electrode 507 constructed of a laminate of Ti/Al/Au is formed on the harrier layer 505 and within the recess 508. Moreover, a cathode ohmic electrode 506 constructed of a laminate of Ti/Al/Au is formed on the barrier layer 505. Then, a two-dimensional electron gas channel 504 is generated in the GaN channel layer 503 and in the vicinity of the boundary between the channel layer 503 and the AlGaN barrier layer 505.

The cathode ohmic electrode 506 and the anode ohmic electrode 507 are brought in ohmic contact with the two-dimensional electron gas channel 504 by heat treatment. Then, a Schottky gate electrode 509 constructed of a laminate of WN/Au is formed on the recess 508 and the anode ohmic electrode 507. The Schottky gate electrode 509 is connected to the anode ohmic electrode 507, and the recess 508 is completely wholly covered with the electrode.

In a state in which there is no application voltage, the two-dimensional electron gas channel 504 located just below the Schottky gate electrode 509 put in the recess 508 is depleted by the influence of the Schottky gate electrode 509. Conversely, when the voltage applied across the anode ohmic electrode 507 and the cathode ohmic electrode 506 is a positive voltage (forward bias) that exceeds the threshold voltage, electrons are generated in the two-dimensional electron gas channel 504 located just below the gate electrode 509 with which the recess 508 is covered, and a current flows between the anode ohmic electrode 507 and the cathode ohmic electrode 506.

That is, according to the rectifier of the present embodiment, the rise voltage of the forward bias depends on the threshold voltage at which electrons are generated in the two-dimensional electron gas channel 504 located just below the gate electrode 509. Since the threshold voltage is lower than the rise voltage of the conventional Schottky diode, a rectifier of a low rise voltage can be provided according to the present embodiment.

Although it is possible that a leakage current (parallel conduction) between the anode ohmic electrode 507 and the cathode ohmic electrode 506 occurs unlike the conventional Schottky diode in the present second embodiment, the leakage current between the anode and the cathode can be reduced since it is difficult for the electrons in the two-dimensional electron gas channel 504 to go out of the GaN channel layer 503 due to the existence of the AlGaN layer 511.

### Third Embodiment

Next, FIG. 6 shows the third embodiment of the rectifier of the present invention. In the third embodiment, an AlN/GaN buffer layer 602 having a layer thickness of 500 Å, a channel layer 603 made of undoped GaN having a layer thickness of 2 μm, and a barrier layer 605 made of Al_{0.3}Ga_{0.7}N having a layer thickness of 250 Å are successively formed on a silicon substrate 601.

An anode ohmic electrode 607 constructed of a laminate of Ti/Al/Au and a cathode ohmic electrode 606 constructed of a laminate of Ti/Al/Au are formed on the barrier layer 605. Then, a two-dimensional electron gas (2DEG) channel 604 is generated in the GaN channel layer 603 and in the vicinity of the boundary between the channel layer 603 and the AlGaN barrier layer 605.

The anode ohmic electrode 607 and the cathode ohmic electrode 606 are brought in ohmic contact with the two-dimensional electron gas channel 604 by heat treatment. Moreover, a recess 608 having a depth of 180 Å is formed by etching in the AlGaN barrier layer 605. A Ta₂O₅ dielectric 612 having a film thickness of 500 Å is formed on the surface of the barrier layer 605. Then, a gate electrode 609 constructed of a laminate of WN/Au is formed on the dielectric 612.

The gate electrode 609 extends from above the anode ohmic electrode 607 over to the barrier layer 605 and is connected to the anode ohmic electrode 607. Moreover, the recess 608 is wholly covered with the gate electrode 609. The gate electrode 609, the dielectric 612 and the AlGaN barrier layer 605 constitute a MIS (metal-insulator-semiconductor) gate structure. Moreover, the AlGaN barrier layer 605 and the GaN channel layer 603 constitute a heterojunction portion.

In a state in which there is no application voltage, the two-dimensional electron gas channel 604 located just below the recess 608 is depleted by the influence of the gate electrode 609. Conversely, when the voltage applied across the anode ohmic electrode 607 and the cathode ohmic electrode 606 is a positive voltage (forward bias), electrons are generated in the two-dimensional electron gas channel 604 located just below the gate electrode 609 with which the recess 608 is covered, and a current flows between the anode ohmic electrode 607 and the cathode ohmic electrode 606.

In the rectifier of the present embodiment, the rise voltage of the forward bias depends on the threshold voltage at which electrons are generated in the two-dimensional electron gas channel 604 located just below the gate electrode 609. Since the threshold voltage is lower than the rise voltage of the conventional Schottky diode, a rectifier of a low rise voltage can be provided according to the present embodiment.

Moreover, the Ta₂O₅ dielectric 612 owned by the present embodiment has a high dielectric constant and a passivation effect on the semiconductor surface, and therefore, Ta₂O₅ is particularly effective as a dielectric material. It is noted that other effective dielectric materials include Nb₂O₅, HfO₂ and Si₂N₃.

### Fourth Embodiment

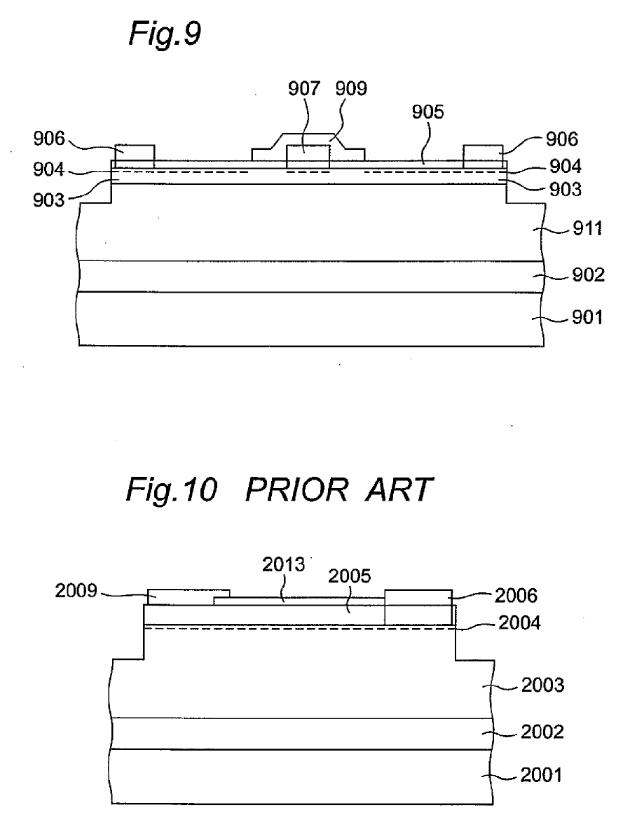

Next, FIG. 9 shows the fourth embodiment of the rectifier of the present invention. In the present fourth embodiment, an AlN/GaN butter layer 902 having a layer thickness of 500 Å, a layer 911 made of undoped Al_{0.1}Ga_{0.9}N having a layer thickness of 2 μm, a channel layer 903 made of undoped GaN having a layer thickness of 500 Å and a barrier layer 905 made of Al_{0.3}Ga_{0.7}N having a layer thickness of 100 Å are successively formed on a silicon substrate 901. The barrier layer 905, the channel layer 903 and the AlGaN layer 911 constitute a double heterojunction structure portion.

An anode ohmic electrode 907 constructed of a laminate of Ti/Al/Au is formed on the barrier layer 905. Moreover, a cathode ohmic electrode 906 constructed of a laminate of Ti/Al/Au is formed on the barrier layer 905. Then, a two-dimensional electron gas channel 904 is generated in the GaN channel layer 903 and in the vicinity of the boundary between the channel layer 903 and the AlGaN barrier layer 905. Moreover, the cathode ohmic electrode 906 and the anode ohmic electrode 907 are brought in ohmic contact with the two-dimensional electron gas channel 904 by heat treatment.

The present embodiment has a Schottky gate electrode 909 formed on the anode ohmic electrode 907 and the AlGaN barrier layer 905. The Schottky gate electrode 909 is constructed of a laminate of WN/Au.

In a state in which there is no application voltage, the two-dimensional electron gas channel 904 located just below the Schottky gate electrode 909 is depleted by the influence of the Schottky gate electrode 909. Conversely, when the voltage applied across the anode ohmic electrode 907 and the cathode ohmic electrode 906 is a positive voltage (forward bias), electrons are generated in the two-dimensional electron gas channel 904 located just below the Schottky gate electrode 909, and a current flows between the anode ohmic electrode 907 and the cathode ohmic electrode 906.

In the rectifier of the present embodiment, the rise voltage of the forward bias depends on the threshold voltage at which electrons are generated in the two-dimensional electron gas channel 904 located just below the gate electrode 909. Since the threshold voltage is lower than the rise voltage of the conventional Schottky diode, a rectifier of a low rise voltage can be provided according to the present embodiment.

Although the layer thickness of the AlGaN barrier layer 905 has been set to 100 Å in the present embodiment, it is most desirable to set the layer thickness of the barrier layer 905 to 80 Å to 100 Å. Moreover, since the threshold voltage rises if the layer thickness of the barrier layer is excessively thin, the layer thickness of the barrier layer 905 should desirably be not smaller than 20 Å and more desirably be not smaller than 50 Å.

Although the depth of the recess formed in the AlGaN barrier layer has been set to 150 Å in the first through third embodiments, it is most desirable to set the depth of the recess to 150 Å to 170 Å when the layer thickness of the AlGaN barrier layer is 250 Å. Moreover, since the threshold voltage rises if the depth of the recess is excessively deep, the depth of the recess should desirably be not greater than 230 Å and more desirably be not greater than 200 Å. Moreover, although the semiconductor channel layer has been made of undoped GaN in the first through fourth embodiments, the layer may be made of another III-V group compound semiconductor of GaAs, InP, InGaAsP or the like. Moreover, although the gate electrode has been the Schottky gate electrode in the first, second and fourth embodiments, the gate electrode is not limited to the Schottky electrode in the present invention but allowed to be, for example, a gate electrode that constitutes a MIS gate structure as described in the third embodiment.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A rectifier comprising:
a semiconductor channel layer formed on a substrate;
a barrier layer that is formed on the semiconductor channel layer and constitutes a heterojunction portion with the semiconductor channel layer;
an anode ohmic electrode connected to the semiconductor channel layer;
a cathode ohmic electrode connected to the semiconductor channel layer;
a gate electrode that is connected to the anode ohmic electrode and formed on the heterojunction portion; and
a recess that is formed in the barrier layer and wholly covered with the gate electrode.

2. The rectifier as claimed in claim 1, wherein
the semiconductor channel layer is made of a III-V group compound semiconductor.

3. The rectifier as claimed in claim 1, wherein
the semiconductor channel layer is made of a GaN semiconductor.

4. The rectifier as claimed in claim 1, wherein
the gate electrode is a Schottky electrode.

5. The rectifier as claimed in claim 1, comprising:
a dielectric that is formed in between the gate electrode and the barrier layer and constitutes a MIS structure portion with the gate electrode and the barrier layer.

6. The rectifier as claimed in claim 1, comprising:
a semiconductor layer that is formed in between the substrate and the semiconductor channel layer and constitutes a double heterojunction structure portion with the barrier layer and the semiconductor channel layer.

7. A rectifier comprising:
a semiconductor channel layer formed on a substrate;
a barrier layer that is formed on the semiconductor channel layer and constitutes a heterojunction portion with the semiconductor channel layer;
an anode ohmic electrode connected to the semiconductor channel layer;
a cathode ohmic electrode connected to the semiconductor channel layer; and
a gate electrode that is connected to the anode ohmic electrode and formed on the heterojunction portion,
the barrier layer having a layer thickness of not greater than 100 Å.
